(19) United States
(12) Patent Application Publication
(10) Pub. No.: US 2026/0164740 A1
(43) Pub. Date: Jun. 11, 2026

(54) SEMICONDUCTOR STRUCTURE AND FABRICATING METHOD THEREOF

(71) Applicant: HON HAI PRECISION INDUSTRY CO., LTD., New Taipei City (TW)

(72) Inventor: Chih-Yen SHEN, Hsinchu City (TW)

(21) Appl. No.: 19/032,110

(22) Filed: Jan. 19, 2025

(30) Foreign Application Priority Data
Dec. 6, 2024 (TW) 113147367

(51) Int. Cl. H10D 62/85; H01L 21/02

(52) U.S. Cl. CPC H10D 62/8503; H10P 14/3216; H10P 14/3416

(57) ABSTRACT

A semiconductor structure includes a substrate, a first group III nitride structure disposed on the substrate, a plurality of carbon blocks, and a second group III nitride structure. An upper surface of the first group III nitride structure has a plurality of pits. The carbon blocks are located in the pits. The second group III nitride structure is disposed on the first group III nitride structure and the carbon blocks. A method of fabricating the semiconductor structure includes the following operations. The first group III nitride structure is formed on the substrate, in which the upper surface of the first group III nitride structure has the pits. The carbon blocks are formed in the pits. The second group III nitride structure is formed on the first group III nitride structure and the carbon blocks.

### CROSS-REFERENCE TO RELATED APPLICATION

This application claims priority to Taiwan Application Serial Number 113147367, filed Dec. 6, 2024, which is herein incorporated by reference in its entirety.

### BACKGROUND

### Field of Invention

The present disclosure relates to a semiconductor structure and a method of fabricating the semiconductor structure.

### Description of Related Art

Generally speaking, during a semiconductor structure process of growing a group III nitride layer on a substrate, the semiconductor structure is prone to bending and/or cracking due to differences in lattice constants and thermal expansion coefficients between the substrate and the group III nitride layer. Therefore, there is an urgent need to develop a semiconductor structure to improve the above problems.

### SUMMARY

The present disclosure provides a semiconductor structure including a substrate, a first group III nitride structure, a plurality of carbon blocks, and a second group III nitride structure. The first group III nitride structure is disposed on the substrate, in which an upper surface of the first group III nitride structure has a plurality of pits. The carbon blocks are located in the pits. The second group III nitride structure is disposed on the first group III nitride structure and the carbon blocks.

The present disclosure provides a method of fabricating the semiconductor structure, and the method includes the following operations. The first group III nitride structure is formed on the substrate, in which the upper surface of the first group III nitride structure has a plurality of pits. The carbon blocks are formed in the pits. The second group III nitride structure is formed on the first group III nitride structure and the carbon blocks.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings.

FIG. 1 is a method of fabricating a semiconductor structure, in accordance with some embodiments of the present disclosure.

FIGS. 2-6 are cross-sectional views of intermediate stages of fabricating the semiconductor structure, in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

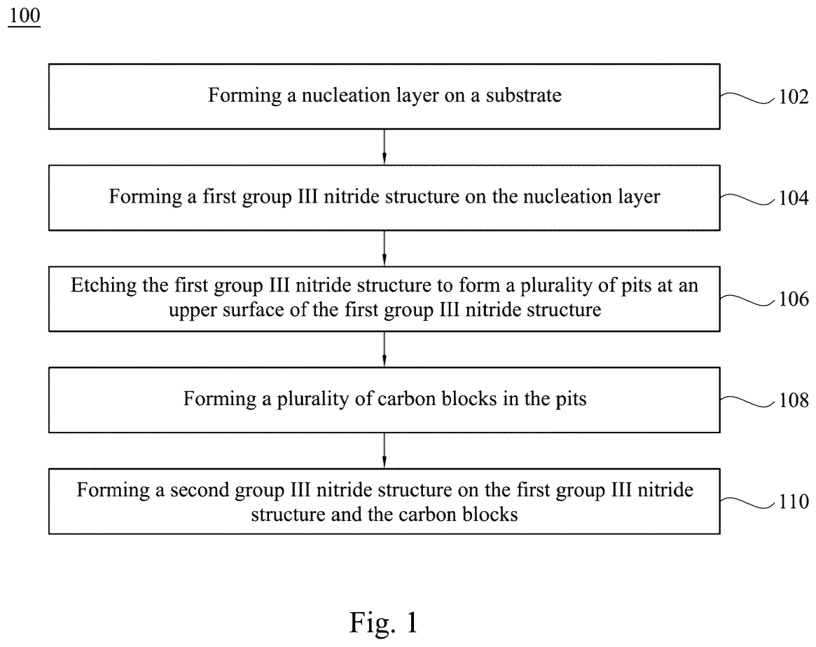

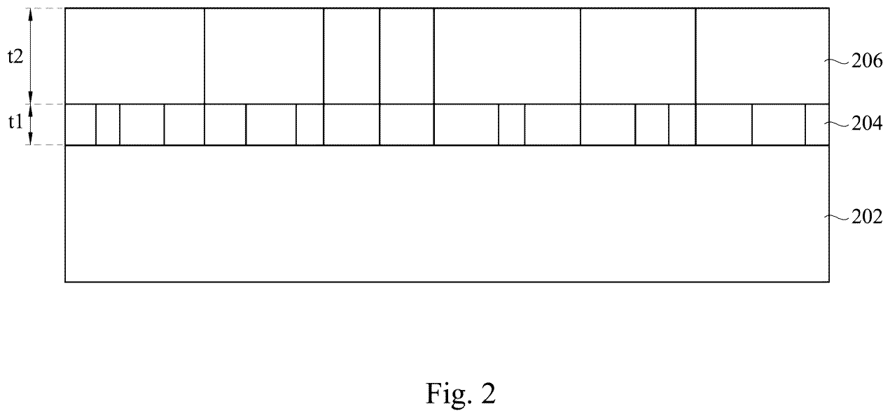

FIG. 1 is a method 100 of fabricating a semiconductor structure, in accordance with some embodiments of the present disclosure. The method 100 includes operations 102, 104, 106, 108, and 110. FIGS. 2-6 are cross-sectional views illustrating intermediate stages of fabricating the semiconductor structure 200, in accordance with various embodiments of the present disclosure. Refer to FIGS. 1 and 2. In operation 102, a nucleation layer 204 is formed on a substrate 202. The nucleation layer 204 is formed by an epitaxy method such as metal-organic chemical vapor deposition (MOCVD), hydride vapor phase epitaxy (HVPE), molecular beam epitaxy (MBE), sputtering, ionic electroplating, or other suitable epitaxy methods. In some embodiments, the nucleation layer 204 includes a group III nitride, SiC, or carbon, and the group III nitride is, for example AlN, AlGaN, GaN, InGaN, InAlN, or combinations thereof. In some embodiments, a thickness t1 of the nucleation layer 204 is 50 nm to 500 nm, such as 50, 100, 150, 200, 250, 300, 350, 400, 450, 500 nm. In some embodiments, the substrate 202 includes Si, SiC, sapphire, MgO, GaN, ZnO, AlN, Ga₂O₃, Al₂O₃, or combinations thereof, in which Si is, for example Si having a (111) crystal plane. Refer to FIGS. 1 and 2. In operation 104, a first group III nitride structure 206 is formed on the nucleation layer 204. As shown in FIG. 2, the first group III nitride structure 206 is formed on the substrate 202 and the nucleation layer 204. In some embodiments, the first group III nitride structure 206 includes a single group III nitride layer or multiple group III nitride layers. In some embodiments, the first group III nitride structure 206 includes AlN, AlGaN, InAlN, InGaN, GaN, or combinations thereof. In some embodiments, the first group III nitride structure 206 includes a compound with a structure shown as Al_{X}Ga_{1-X}N, in which X is 0.15 to 1, such as 0.15, 0.2, 0.25, 0.3, 0.35, 0.4, 0.45, 0.5, 0.55, 0.6, 0.65, 0.7, 0.75, 0.8, 0.85, 0.9, 0.95, or 1. In some embodiments, the first group III nitride structure 206 includes one or more superlattice structure(s). Each superlattice structure(s) include(s) any two layers or multiple layers of more than two of AlN layer, AlGaN layer, InAlN layer, and GaN layer that are alternatively stacked, such as AlN layer and AlGaN layer are alternatively stacked, in which the AlGaN layer includes Al_{X}Ga_{1-X}N (X is 0.15 to 0.45, such as 0.15, 0.2, 0.25, 0.3, 0.35, 0.4, or 0.45, or X is 0.3 to 0.6, such as 0.3, 0.35, 0.4, 0.45, 0.5, 0.55, or 0.6). In some embodiments, the first group III nitride structure 206 formed on the nucleation layer 204 is formed by an epitaxy method such as MOCVD, HVPE, MBE, sputtering, ionic electroplating, or other suitable epitaxy methods, such that the first group III nitride structure 206 is grown on the nucleation layer 204. In some embodiments, a thickness t2 of the first group III nitride structure 206 is 50 nm to 9000 nm, such as 50, 500, 1000, 1500, 2000, 2500, 3000, 3500, 4000, 4500, 5000, 5500, 6000, 6500, 7000, 7500, 8000, 8500, or 9000 nm. When the thickness t2 of the first group III nitride structure 206 is 50 nm to 1500 nm (a total thickness of the first group III nitride structure 206 and a structure formed on the first group III nitride structure 206 subsequently, for example, a second group III nitride structure, is 50 nm to 3000 nm, such as 50, 100, 500, 1000, 1500, 2000, 2500, or 3000 nm), the structure is suitable for a low voltage operation product. When the thickness t2 of the first group III nitride structure 206 is 300 nm to 5000 nm (a total thickness of the first group III nitride structure 206 and a structure formed on the first group III nitride structure 206 subsequently, for example, a second group III nitride structure, is 5200 nm to 9000 nm, such as 5200, 6000, 6500, 7000, 7500, 8000, 8500, or 9000 nm), the structure is suitable for a high voltage operation product. When the thickness t2 of the first group III nitride structure 206 is 6000 nm to 9000 nm (a total thickness of the first group III nitride structure 206 and a structure formed on the first group III nitride structure 206 subsequently, for example, a second group III nitride structure, is 7500 nm to 14000 nm, such as 7500, 8000, 9000, 10000, 11000, 12000, 13000, or 14000 nm), the structure is suitable for a vertical device structure or a ultra-high voltage semiconductor device. Using the aforementioned ranges of the thickness t2 of the first group III nitride structure 206 according to the aforementioned types of the semiconductor devices (the low and high voltage operation products, the vertical device structure, or the ultra-high voltage semiconductor device) can achieve the optimum warpage of the semiconductor structure.

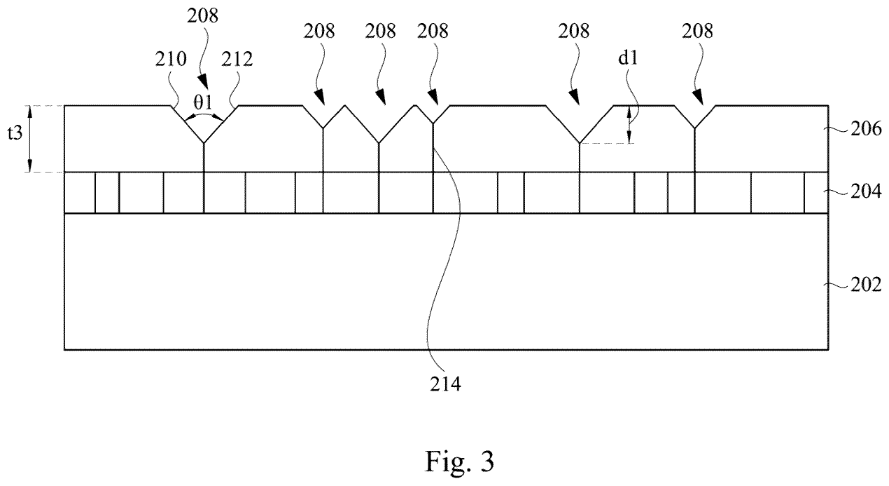

Refer to FIGS. 1 and 3. In operation 106, the first group III nitride structure 206 is etched to form a plurality of pits 208 at an upper surface of the first group III nitride structure 206. In some embodiments, the pits 208 are conical pits, and cross-sections of the pits 208 are inverted triangle shapes. In some embodiments, top view shapes of the pits 208 are hexagons. In some embodiments, depths d1 of the pits 208 are 30 nm to 300 nm, such as 30, 40, 50, 60, 70, 80, 90, 100, 150, 200, 250, or 300 nm. When the thickness t2 of the first group III nitride structure 206 is less than 7000 nm and the depths d1 of the pits 208 are 30 nm to 100 nm, shielded dislocations 214 can be effectively blocked and the first group III nitride structure 206 can have a highly planarized upper surface, which is beneficial to electrical characteristics of subsequent semiconductor device fabrication. The thickness t2 of the first group III nitride structure 206 with 7000 nm to 9000 nm can be suitable for the depths d1 of the pits 208 with 30 nm to 300 nm. In some embodiments, the pits 208 have first sidewall 210 and second sidewall 212 that are intersected with each other in a cross-section, and an included angle θ1 of the first sidewall 210 and the second sidewall 212 is 20 degrees to 120 degrees, such as 20, 30, 40, 50, 60, 70, 80, 90, 100, 110, or 120 degrees. The pits 208 are selectively formed on the dislocations 214 of the first group III nitride structure 206. Forming the pits 208 can decrease dislocation densities of the structures or layers formed on the first group III nitride structure 206 subsequently (such as a second group III nitride structure), such that the quality and the yield of the semiconductor structure 200 enhance. In some embodiments, after etching the first group III nitride structure 206, the thickness of the first group III nitride structure 206 decreases, that is, a thickness t3 after etching the first group III nitride structure 206 is less than the thickness t2 before etching the first group III nitride structure 206. In some embodiments, etching the first group III nitride structure 206 includes in-situ etching the first group III nitride structure 206. In some embodiments, etching the first group III nitride structure 206 is performed by the dry etching process or the wet etching process. In some embodiments, etching the first group III nitride structure 206 is performed by chlorine gas plasma, nitrogen gas plasma, hydrogen gas plasma, or combinations thereof.

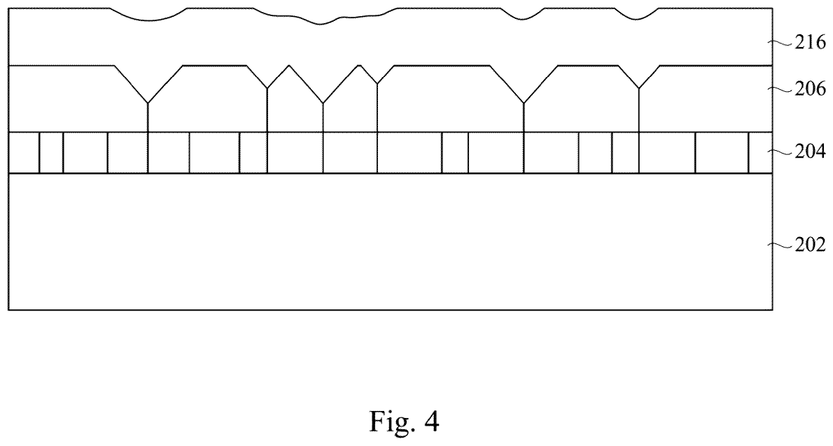

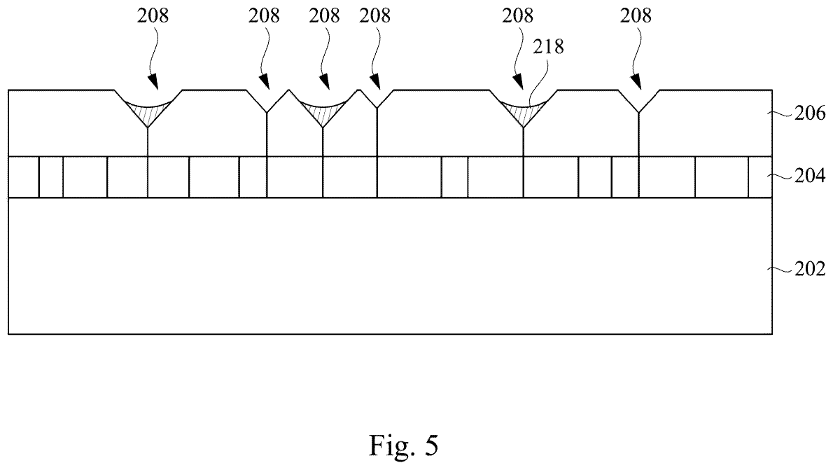

Refer to FIGS. 1, 3, 4, and 5. In operation 108, a plurality of carbon blocks 218 is formed in the pits 208. In some embodiments, forming the carbon blocks 218 in the pits 208 includes the following operations. As shown in FIGS. 3-4, a carbon layer 216 is deposited to cover the first group III nitride structure 206 and the pits 208. As shown in FIGS. 4-5, the carbon layer 216 is etched to form the carbon blocks 218 in the pits 208. In some embodiments, the carbon blocks 218 partially fill the pits 208. In some embodiments, the carbon blocks 218 are only positioned in portions of the pits 208, as shown in FIG. 5. In some embodiments, all pits 208 have the carbon blocks 218. In some embodiments, whether the carbon blocks 218 are formed in the pits 208 is affected by aspect ratios of the pits 208 and/or an etching rate and an etching time of the carbon layer 216. In some embodiments, the bigger the aspect ratios of the pits 208, the slower the etching rate of the carbon layer 216, and/or the shorter the etching time of the carbon layer 216 are, the easier it is for the carbon blocks 218 to form in the pits 208. On the contrary, the smaller the aspect ratios of the pits 208, the faster the etching rate of the carbon layer 216, and/or the longer the etching time of the carbon layer 216 are, the less likely it is for the carbon blocks 218 to form in the pits 208. In some embodiments, the carbon blocks 218 shield the dislocations 214. In some embodiments, the carbon layer 216 is deposited by the deposition process such as the chemical vapor deposition (CVD) process, the physical vapor deposition (PVD) process, the atomic layer deposition (ALD) process, or other suitable deposition process. In some embodiments, before depositing the carbon layer 216, methods such as MOCVD, HVPE, MBE, sputtering, ionic electroplating, or other suitable epitaxy methods are used to introduce methane gas, ethane gas, propane gas, hexane gas, acetylene gas, ethylene gas, propylene gas, butane gas, butene gas, cyclopentane, cyclopentene, hexene, N(CH₃)₃, or combinations thereof for the chemical deposition precursor(s) of the carbon layer 216. In some embodiments, depositing the carbon layer 216 to cover the first group III nitride structure 206 and the pits 208 is depositing the carbon layer 216 by methane gas, ethane gas, propane gas, hexane gas, acetylene gas, ethylene gas, propylene gas, butane gas, butene gas, cyclopentane, cyclopentene, hexene, N(CH₃)₃, or combinations thereof. In some embodiments, the carbon layer 216 includes polycrystalline carbon, amorphous carbon, or a combination thereof, in which polycrystalline carbon includes graphite, Al₄C₃, or a combination thereof, and amorphous carbon includes hard carbon, soft carbon, or a combination thereof. In some embodiments, etching the carbon layer 216 includes in-situ dry etching the carbon layer 216. In some embodiments, the carbon layer 216 is etched to form the carbon blocks 218 in the pits 208 using ammonia gas as a main etching gas and a carrier gas such as nitrogen or argon gases to perform dry etching process, reactive-ion etching process, or the introduction of the remote plasma. When the carbon layer 216 is etched using ammonia gas as a main etching gas and a carrier gas such as nitrogen or argon gases, nitrogen and ammonia gases are reacted with the carbon layer 216 to form HCN gas to etch the carbon layer 216. At the same time, the dislocation defects on the upper surface of the first group III nitride structure 206 are also repaired. When the carbon layer 216 is etched to form the carbon blocks 218 in the pits 208 using ammonia gas as a main etching gas and a carrier gas such as nitrogen or argon gases to perform dry etching process, the pits 208 can cover the center of the dislocation defects of the bottom of the pits 208, such that the dislocations 214 may not extend to the structures or the layers formed subsequently on the first group III nitride structure 206 (the second group III nitride structure), thereby improving the quality and the yield of the semiconductor structure. When in-situ etching the carbon layer 216 or etching the carbon layer 216 by the ammonia gas to form the carbon blocks 218 in the pits 208, the carbon blocks 218 can serve as an epitaxial blocking layer, such that the structures or the layers formed subsequently on the first group III nitride structure 206 (the second group III nitride structure) may reduce the dislocation density, thereby improving the quality and the yield of the semiconductor structure. In some embodiments, etching the carbon layer 216 to form the carbon blocks 218 in the pits 208 is performed by a plasma apparatus using nitric oxide, nitrous oxide, or oxygen gas/ozone.

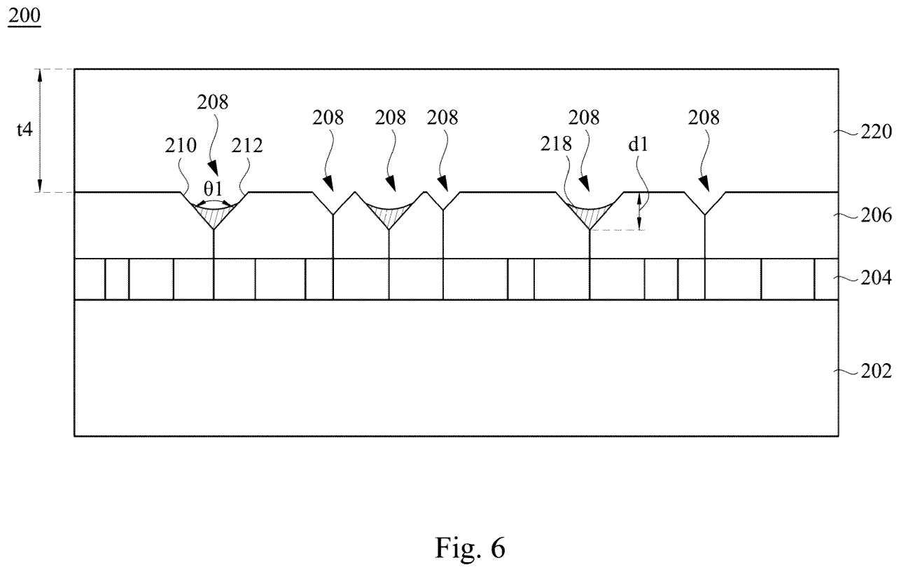

Refer to FIGS. 1 and 6. In operation 110, a second group III nitride structure 220 is formed on the first group III nitride structure 206 and the carbon blocks 218. In some embodiments, a thickness t4 of the second group III nitride structure 220 is 800 nm to 9000 nm, such as 800, 900, 1000, 2000, 3000, 4000, 5000, 6000, 7000, 8000, or 9000 nm. When the depths d1 of the pits 208 are 30 nm to 100 nm and the thickness t4 of the second group III nitride structure 220 is 800 nm to 2500 nm, it meets the surface planarization requirements of the semiconductor structure and can achieve the purpose of the final curvature control of the most epitaxial structure substrate. When the depths d1 of the pits 208 are 100 nm to 300 nm and the thickness t4 of the second group III nitride structure 220 is 1500 nm to 4500 nm, it meets the surface planarization requirements of the semiconductor structure and can achieve the purpose of the final curvature control of the most epitaxial structure substrate. When the depths d1 of the pits 208 are 100 nm to 300 nm and the thickness t4 of the second group III nitride structure 220 is 4500 nm to 9000 nm, it is suitable for the structural stacking method of the special devices, such as the vertical device structure. When the aforementioned thickness t4 of the second group III nitride structure 220 are formed on the aforementioned depths d1 of the pits 208, the flatness of the upper surface of the second group III nitride structure 220 can be ensured, thereby improving the quality and the yield of the semiconductor structure. In some embodiments, the second group III nitride structure 220 is formed by, for example, MOCVD, HVPE, MBE, sputtering, ionic electroplating, or other suitable epitaxy methods. When the second group III nitride structure 220 is formed on the first group III nitride structure 206 and the carbon blocks 218, the dislocation density of the second group III nitride structure 220 reduces. Thus, a thickness or the composition of the semiconductor structure 200 may be suitable for a broader epitaxial stacking methods or different thickness designs.

In some embodiments, the second group III nitride structure 220 includes single or multiple group III nitride layers. In some embodiments, the second group III nitride structure 220 includes AlN, AlGaN, InAlN, InGaN, GaN, AlYN, AlScN, or combinations thereof. In some embodiments, the second group III nitride structures 220 and the first group III nitride structures 206 include different materials. In some embodiments, the second group III nitride structures 220 and the first group III nitride structures 206 include the same materials. In some embodiments, the second group III nitride structure 220 includes one or more superlattice structure, in which each superlattice structure includes any two layers or multiple layers of more than two of AlN layer, AlGaN layer, GaN layer, InAlN layer, and InGaN layer that are alternatively stacked, such as AlN layer and AlGaN layer are alternatively stacked. In some embodiments, the second group III nitride structure 220 is multiple group III nitride layers, such as the second group III nitride structure 220 includes a first superlattice structure, a second superlattice structure, a first GaN layer, a second GaN layer, an AlGaN layer, and a third GaN layer in order from the bottom to the top. In some embodiments, the first superlattice structure includes AlN layer and Al_{X}Ga_{1-X}N layer that are alternatively stacked, and X is 0.3 to 0.6, such as 0.3, 0.35, 0.4, 0.45, 0.5, 0.55, or 0.6; and the second superlattice structure includes AlN layer and Al_{Y}Ga_{1-Y}N layer that are alternatively stacked, and Y is 0.15 to 0.45, such as 0.15, 0.2, 0.25, 0.3, 0.35, 0.4, or 0.45. In some embodiments, thicknesses of the first and second superlattice structures are respectively 1000 nm to 2500 nm, such as 1000, 1350, 1500, 1750, 2000, 2250, or 2500 nm. In some embodiments, a thickness of the first GaN layer is 500 nm to 3000 nm, such as 500, 750, 1000, 1250, 1500, 1750, 2000, 2250, 2500, 2750, or 3000 nm. In some embodiments, the first GaN layer is a GaN layer doped with carbon, in which the doping concentration of the carbon is 2×10¹⁶ cm⁻³ to 5×10²¹ cm⁻³, such as 2×10¹⁶, 5×10¹⁶, 1×10¹⁷, 5×10¹⁷, 1×10¹⁸, 5×10¹⁸, 1×10¹⁹, 5×10¹⁹, 1×10²⁰, 5×10²⁰, 1×10²¹, or 5×10²¹ cm⁻³. In some embodiments, the first GaN layer includes two or more first GaN layers with different carbon doping concentrations, for example, the carbon doping concentration of the first GaN layer from the bottom to the top is high to low, low to high, low to high to low, or any combinations of the above changes. In some embodiments, a thickness of the second GaN layer is 150 nm to 600 nm, such as 150, 200, 250, 300, 350, 400, 450, 500, 550, or 600 nm. In some embodiments, a thickness of the AlGaN layer is 10 nm to 35 nm, such as 10, 15, 20, 25, 30, or 35 nm; and a thickness of the third GaN layer includes 50 nm to 120 nm, such as 50, 60, 70, 80, 90, 100, 110, or 120 nm. In some embodiments, the third GaN layer includes a nitride of 2A group elements such as Be, Mg, Ca, Sr, Ba, Ra, or combinations thereof and GaN, in which GaN can also be replaced by AlN. In some embodiments, the first and second superlattice structures are replaced by the AlGaN structure. In some embodiments, the AlGaN structure includes a plurality of AlGaN layers (the first, second, and third AlGaN layers), and the Al content of each layer gradually decreases. The first AlGaN layer is Al_{X}Ga_{1-X}N, and X is 0.6 to 0.9, such as 0.6, 0.65, 0.7, 0.75, 0.8, 0.85, or 0.9. The second AlGaN layer is Al_{Y}Ga_{1-Y}N, and Y is 0.4 to 0.6, such as 0.4, 0.45, 0.5, 0.55, or 0.6. The third AlGaN layer is Al_{Z}Ga_{1-Z}N, and Z is 0.05 to 0.4, such as 0.05, 0.1, 0.15, 0.2, 0.25, 0.3, 0.35, or 0.4. In some embodiments, the AlGaN structure includes four, five, or more AlGaN layers. In some embodiments, the second group III nitride structure 220 includes a first GaN layer, a second GaN layer, an AlGaN layer, and a third GaN layer. Refer to the aforementioned embodiments for the materials and the thicknesses of each layer in the second group III nitride structure 220.

In some embodiments, a dislocation density of the second group III nitride structure 220 is 5×10¹⁷ cm⁻² to 1×10¹⁹ cm⁻², such as 5×10¹⁷, 7.5×10¹⁷, 1×10¹⁸, 2.5×10¹⁸, 5×10¹⁸, 7.5×10¹⁸, or 1×10¹⁹ cm⁻². In some embodiments, voids are in the second group III nitride structure 220. Compared to a structure with no voids in the second group III nitride structure 220, a structure with voids in the second group III nitride structure 220 can present different stress accumulation and interface area of the second group III nitride structure 220, and a contact area of the second group III nitride structure 220 and the carbon blocks 218 reduces, thereby reducing the generation of defects caused by heterogeneous junctions. It is helpful for the improvement of the quality and the yield of the semiconductor structure. In some embodiments, forming the second group III nitride structure 220 on the first group III nitride structure 206 and the carbon blocks 218 includes performing selective epitaxy growth (SEG). In detail, when the second group III nitride structure 220 is formed on the first group III nitride structure 206 and the carbon blocks 218, the second group III nitride structure 220 on the surface of the first group III nitride structure 206 uncovered by the carbon blocks 218 has a relatively fast epitaxial growth rate because the surface of the carbon blocks 218 can serve as a hard mask to block or retard the epitaxial growth of the second group III nitride structure 220. When forming the second group III nitride structure 220 on the first group III nitride structure 206 and the carbon blocks 218 is performed by SEG, the dislocation density of the second group III nitride structure 220 decreases, thereby improving the quality and the yield of the semiconductor structure.

Refer to FIG. 6. The present disclosure provides the semiconductor structure 200. The semiconductor structure 200 includes the substrate 202, the nucleation layer 204, the first group III nitride structure 206, the carbon blocks 218, and the second group III nitride structure 220. The first group III nitride structure 206 is disposed on the substrate 202, in which the upper surface of the first group III nitride structure 206 has the pits 208. The carbon blocks 218 are located in the pits 208. The second group III nitride structure 220 is disposed on the first group III nitride structure 206 and the carbon blocks 218. In some embodiments, the nucleation layer 204 is between the substrate 202 and the first group III nitride structure 206. In some embodiments, the first group III nitride structure 206 includes AlN, AlGaN, InAlN, InGaN, GaN, or combinations thereof; and the second group III nitride structure 220 includes AlN, AlGaN, InAlN, InGaN, GaN, AlYN, AlScN, or combinations thereof. In some embodiments, the pits 208 are conical pits, and the cross-sections of the pits 208 are inverted triangle shapes. In some embodiments, the depths d1 of the pits 208 are 30 nm to 300 nm, such as 30, 40, 50, 60, 70, 80, 90, 100, 150, 200, 250, or 300 nm. In some embodiments, the pits 208 have the first sidewall 210 and the second sidewall 212 that are intersected with each other in the cross-section, and the included angle θ1 of the first sidewall 210 and the second sidewall 212 is 20 degrees to 120 degrees, such as 20, 30, 40, 50, 60, 70, 80, 90, 100, 110, or 120 degrees. In some embodiments, the carbon blocks 218 are only positioned in a portion of the pits 208. Refer to the aforementioned embodiments and/or the effects of the method of fabricating the semiconductor structure 200 for the embodiments and/or the effects the substrate 202, the nucleation layer 204, the first group III nitride structure 206, the carbon blocks 218, the second group III nitride structure 220, and the pits 208.

In summary, in the semiconductor structure and the fabricating method thereof provided by the present disclosure, the carbon blocks cover the center of the dislocation defects of the bottom of the pits, such that the dislocations may not extend to the second group III nitride structure. Besides, the second group III nitride structure is disposed on the first group III nitride structure and the carbon blocks, such that the dislocation density of the second group III nitride structure decreases. The aforementioned features may avoid the following situations. Excessive bending variation of the substrate occurs during the epitaxial process of the first and second group III nitride structures. As a result, the first and second group III nitride structures are cracked during cooling of the epitaxial process or the semiconductor structure is fragmented during front/back-end of line subsequently. In other words, the semiconductor structure and the fabricating method thereof of the present disclosure may improve the quality and the yield of the semiconductor structure.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A semiconductor structure, comprising:
a substrate;
a first group III nitride structure disposed on the substrate, wherein an upper surface of the first group III nitride structure has a plurality of pits;
a plurality of carbon blocks located in the pits; and
a second group III nitride structure disposed on the first group III nitride structure and the carbon blocks.

2. The semiconductor structure of claim 1, wherein the first group III nitride structure comprises AlN, AlGaN, InAlN, InGaN, GaN, or combinations thereof; and the second group III nitride structure comprises AlN, AlGaN, InAlN, InGaN, GaN, AlYN, AlScN, or combinations thereof.

3. The semiconductor structure of claim 1, wherein the pits are conical pits, and cross-sections of the carbon blocks are inverted triangle shapes.

4. The semiconductor structure of claim 3, wherein top view shapes of the pits are hexagons.

5. The semiconductor structure of claim 1, wherein a depth of the pits is 30 nanometers to 300 nanometers.

6. The semiconductor structure of claim 1, wherein the pits have a first sidewall and a second sidewall that are intersected with each other in a cross-section, and an included angle of the first sidewall and the second sidewall is 20 degrees to 120 degrees.

7. The semiconductor structure of claim 1, wherein the carbon blocks are only positioned in a portion of the pits.

8. A method of fabricating a semiconductor structure, comprising:
forming a first group III nitride structure on a substrate, wherein an upper surface of the first group III nitride structure has a plurality of pits;
forming a plurality of carbon blocks in the pits; and
forming a second group III nitride structure on the first group III nitride structure and the carbon blocks.

9. The method of claim 8, wherein forming the carbon blocks in the pits comprises:
depositing a carbon layer to cover the first group III nitride structure and the pits; and
etching the carbon layer to form the carbon blocks in the pits.

10. The method of claim 9, wherein when depositing the carbon layer to cover the first group III nitride structure and the pits, the carbon layer is deposited by methane gas, ethane gas, propane gas, hexane gas, acetylene gas, ethylene gas, propylene gas, butane gas, butene gas, cyclopentane, cyclopentene, hexene, N(CH₃)₃, or combinations thereof.

11. The method of claim 9, wherein etching the carbon layer to form the carbon blocks in the pits is performed by using nitrogen gas, ammonia gas, argon gas, nitric oxide, nitrous oxide, oxygen gas/ozone, or combinations thereof.
